(19) United States
(12) Patent Application Publication
(10) Pub. No.: US 2026/0362657 A1
(43) Pub. Date: Nov. 12, 2026

(54) DRIVE SYSTEM WITH A THERMAL MANAGEMENT SYSTEM

(71) Applicant: Eaton Intelligent Power Limited, Dublin (IE)

(72) Inventors: Hua Qiang Li, Menomonee Falls, WI (US); Geraldo Nojima, Fort Mill, NC (US); Henrique Teixeira Braga, Belo Horizonte (BR)

(21) Appl. No.: 19/202,246

(22) Filed: May 8, 2025

(51) Int. Cl. H05K 7/20

(52) U.S. Cl. CPC H05K 7/20909; H05K 7/20154

(57) ABSTRACT

A drive system includes: a power converter including: a rectifier; an inverter; a heatsink thermally coupled to one or more of the rectifier and the inverter; an energy storage apparatus electrically connected to the rectifier and the inverter; and a direct current (DC) choke electrically connected to the rectifier and the energy storage apparatus. The system also includes a thermal management system configured to flow a thermal management fluid to transport heat away from the DC choke and to separately transport heat away from the heatsink.

### TECHNICAL FIELD

This disclosure relates to a drive system with a thermal management system.

### BACKGROUND

A power converter, such as a variable speed drive, an adjustable speed drive, or an uninterruptable power supply, may be connected to an alternating current (AC) high-power electrical distribution system, such as a power grid. The power converter drives, powers, and/or controls a machine, or a non-machine type of load.

### SUMMARY

In one aspect, a drive system includes: a power converter including: a rectifier; an inverter; a heatsink thermally coupled to one or more of the rectifier and the inverter; an energy storage apparatus electrically connected to the rectifier and the inverter; and a direct current (DC) choke electrically connected to the rectifier and the energy storage apparatus. The system also includes a thermal management system configured to flow a thermal management fluid to transport heat away from the DC choke and to separately transport heat away from the heatsink.

Implementations may include one or more of the following features.

The thermal management system may be configured to flow the thermal management fluid in a first fluid pathway and a second fluid pathway that is at least partially distinct from the first fluid pathway. The heatsink may be in the first fluid pathway, and the DC choke may be in the second fluid pathway. The drive system also may include a wall separating the first fluid pathway and the second fluid pathway.

The energy storage apparatus may include one or more power film capacitors.

The thermal management system may include a fluid handling assembly configured to intake a thermal management fluid at an inlet region and to expel the thermal management fluid through an outlet region. The fluid handling assembly may include a blower. The inlet region of the thermal management system may be configured to intake the thermal management fluid from the heatsink and the outlet region may be configured to expel the thermal management fluid through the outlet region and toward the DC choke. In operational use, the DC choke may be above the fluid handling assembly. The fluid handling assembly of the thermal management system may be configured to: flow the thermal management fluid in a first fluid pathway past the heatsink and through the inlet region, flow the thermal management fluid in a second fluid pathway past the DC choke and through the inlet region, and expel the thermal management fluid from the first fluid pathway and the second fluid pathway through the outlet region. The outlet region of the fluid handling assembly may be adjustable such that a direction fluid is expelled through the outlet region is adjustable. The fluid handling assembly may include one or more blowers, and the thermal management fluid may include air.

The drive system also may include an enclosure. The rectifier, the inverter, the heatsink, the energy storage apparatus, and the DC choke may be inside the enclosure; and, in operational use, the DC choke may be in a bottom portion of the enclosure. In some implementations, the rectifier, the inverter, the heatsink, the energy storage apparatus, and the DC choke are inside the enclosure; and, in operational use, the DC choke is in a top portion of the enclosure. The enclosure may be configured for placement in a first type of mounting arrangement in a first position and for placement in a second type of mounting arrangement in a second position. The first type of mounting arrangement may be a wall mount arrangement, and the second type of mounting arrangement may be a floor mount arrangement.

In another aspect, an enclosure for a drive system includes a region configured to receive an energy storage apparatus and an electronics module comprising a heat sink; a first fluid pathway configured to transport a thermal management fluid to cool the heat sink; and a second fluid pathway configured to transport the thermal management fluid to cool a filter assembly. The filter assembly is configured to be electrically connected to the electronics module and the energy storage apparatus. The enclosure also includes a fluid handling assembly configured to: direct the thermal management fluid through the first fluid pathway and the second fluid pathway; and expel the thermal management fluid to a region outside of the enclosure.

In some implementations, the fluid handling assembly includes one or more blowers, and the thermal management fluid includes air.

In another aspect, heat is transported away from a first portion of a power converter and heat is separately transported away from a second portion of the power converter. The first portion of the power converter includes a heatsink that is thermally coupled to one or more of an inverter, a rectifier, and an energy storage apparatus, and the second portion of the power converter includes a filter assembly electrically connected to the rectifier and the energy storage apparatus.

Implementations may include one or more of the following features.

Separately transporting heat away from the second portion of the power converter may include transporting a thermal management fluid past the filter assembly after passing the thermal management fluid past the heat sink.

Separately transporting heat away from the second portion of the power converter may include transporting a thermal management fluid in a first fluid pathway past the heat sink and in a second fluid pathway past the filter assembly.

Implementations of any of the techniques described herein may include an apparatus, a device, a drive system, an enclosure, and/or a method. The details of one or more implementations are set forth in the accompanying drawings and the description below. Other features will be apparent from the description and drawings, and from the claims.

### DRAWING DESCRIPTION

FIG. 1 is side view of an example of a drive system that includes a thermal management system.

FIG. 2 is a side view of another example of a drive system that includes a thermal management system.

FIG. 3 is a side view of another example of a drive system that includes a thermal management system.

FIG. 4 is a schematic of a drive system that includes a power converter.

FIG. 5 is a side interior view of an example of a three-phase drive system that includes a thermal management system.

FIG. 6 is a front interior view of the drive system of FIG. 5.

FIG. 7 is a perspective view of the drive system of FIG. 5 with the enclosure of the drive system shown as transparent.

FIG. 8 is a side interior view of another example of a three-phase drive system that includes a thermal management system.

FIG. 9A is a cross-sectional view of an example a fluid mover that includes an active element.

FIG. 9B is a perspective view of the active element of the fluid mover of FIG. 9A.

FIG. 10 is a perspective exterior view of an example of a housing of a blower.

FIG. 11 is a perspective exterior view of an example of a housing of a blower.

### DETAILED DESCRIPTION

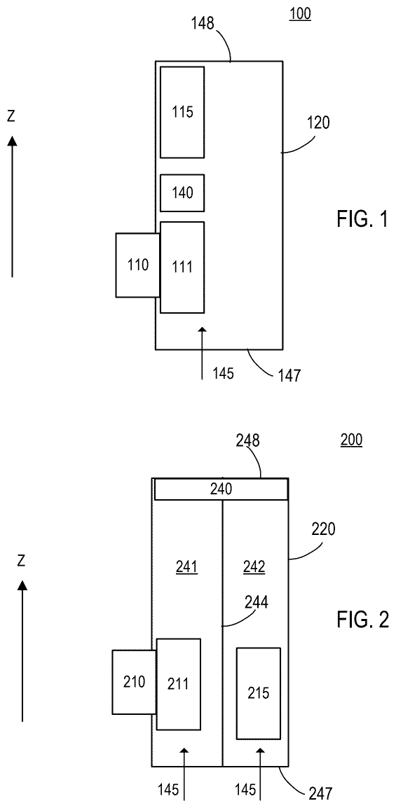

FIG. 1 is a side view of an example of a drive system 100 that includes a thermal management system 140. As discussed below, the thermal management system 140 promotes efficient flow of a thermal management fluid 145 through the drive system 100 to thereby cool the drive system 100 and/or maintain the components of the drive system 100 at a safe operating temperature. The thermal management system 140 includes one or more components that direct the thermal management fluid 145. For example, the thermal management system 140 may include one or more fans, baffles, ducts, blowers, or a combination of such elements. The thermal management fluid 145 is any fluid capable of absorbing heat. For example, the thermal management fluid 145 may be air.

The drive system 100 includes an electronics module 110 mounted to a support 120. The support 120 is any structure capable of supporting the electronics module 110 and the other components of the drive system 100. For example, the support 120 may be an enclosure, a rack, or a frame. The support 120 is made of a durable and rugged material. Examples of materials that may be used for the support 120 include, without limitation, stainless steel, galvanized steel, or a rugged polymer.

The electronics module 110 may be, for example, an inverter and/or a rectifier. The electronics module 110 may be part of a larger system, such as, for example, an adjustable speed drive (ASD), a variable frequency drive (VFD), or a variable speed drive (VSD). Regardless of its specific form, the electronics module 110 includes components (for example, transistors, capacitors, resistors, and/or electrical connections) that emit heat during use, and the electronics module 110 is thermally coupled to a heatsink 111 that dissipates the emitted heat.

The drive system 100 also includes a filter system 115 that is electrically connected to the electronics module 110. The filter system 115 may be, for example, a direct current (DC) choke or a line reactor that filter harmonics or high frequency components that may flow in the electronics module 110 during operational use of the drive system 100. The filter system 115 also generates heat during operational use of the drive system 100.

Excessive heating of the components, systems, and assemblies of the electronics module 110 may degrade the overall performance and/or reduce the lifetime of the electronics module 110. For example, excessive heating may lead to premature component failure, performance degradations, and/or heating of structures external to the electronics module 110. Similarly, excessive or unmitigated heating of the filter system 115 can lead to component failure or reduced system lifetime.

On the other hand, the thermal management system 140 helps to ensure that the electronics module 110 and its components maintain a safe and efficient operating temperature. In operational use, the thermal management system 140 causes the thermal management fluid 145 to flow into an inlet region 147, past and/or through the heatsink 111, the filter system 115, and other components of the drive system 100, and out through an outlet region 148. By causing the thermal management fluid 145 to flow in this manner, the thermal management system 140 transports heat away from the heatsink 111 and the filter system 115, thereby cooling these elements and improving the overall performance of the drive system 100.

Moreover, the thermal management fluid 145 cools the heatsink 111 separately from the filter system 115. For example, in the configuration shown in FIG. 1, the thermal management system 140 draws the thermal management fluid 145 past or through the heatsink 111 generally in the Z direction and expels it toward the filter system 115. In this way, the thermal management fluid 145 encounters the heatsink 111 first and is not heated by the filter system 115 prior to reaching the heatsink 111. This ensures that the heatsink 111 is cooled and also allows for the thermal management fluid 145 to cool the filter system 115.

Other implementations are possible. For example, FIG. 2 shows a side view of another example of a drive system 200 that includes a thermal management system 240 and a support 220. The support 220 includes distinct channels or fluid pathways 241 and 242. Each fluid pathway 241 and 242 is an open space that allows fluid flow. The fluid pathways 241 and 242 are separated by a wall 244. In the example of FIG. 2, the pathways 241 and 242 and the wall 244 extend generally in the Z direction from an inlet region 247 to an outlet region 248. The wall 244 is a solid object that generally prevents fluid exchange between the fluid pathways 241 and 242.

The drive system 200 includes an electronics module 210, which is similar to the electronics module 110 discussed above. The electronics module 210 includes heat-emitting electronic elements, such as, for example, transistors, diodes, switches, resistors, and/or other electronic components. The electronics modules 210 is thermally coupled to a heatsink 211. The drive system 200 also includes a filter system 215 that is electrically connected to the electronics module 210. The filter system 215 may include, for example, one or more inductors.

In the implementation shown in FIG. 2, the heatsink 211 is in the fluid pathway 241 and the filter system 215 is placed in the fluid pathway 242. The heatsink 211 and the filter system 215 may be placed at any location within the respective pathway 241, 242; however, in implementations in which the filter system 215 is relatively heavy, positioning the filter system 215 near the bottom of the pathway 242 may increase the stability when the drive system 200 is installed upright. The thermal management system 240 is positioned above (displaced in the Z direction) the filter system 215 and the heatsink 211.

In operational use, the thermal management system 240 causes the thermal management fluid 145 to flow into the support 220 through the inlet region 247, through the pathways 241 and 242, and out through the outlet region 248. When the thermal management fluid 145 flows in the pathway 241, it passes and/or flows through the heatsink 211 and transports heat away from the heatsink 211. Similarly, when the thermal management fluid flows in the pathway 242, it flows by and/or through the filter system 215 and transports heat away from the filter system 215. Thus, the filter system 215 and the heatsink 211 are cooled separately. Moreover, the two distinct pathways 241 and 242 provide additional flexibility for component placement while still allowing separate cooling of the heatsink 211 and the filter system 215.

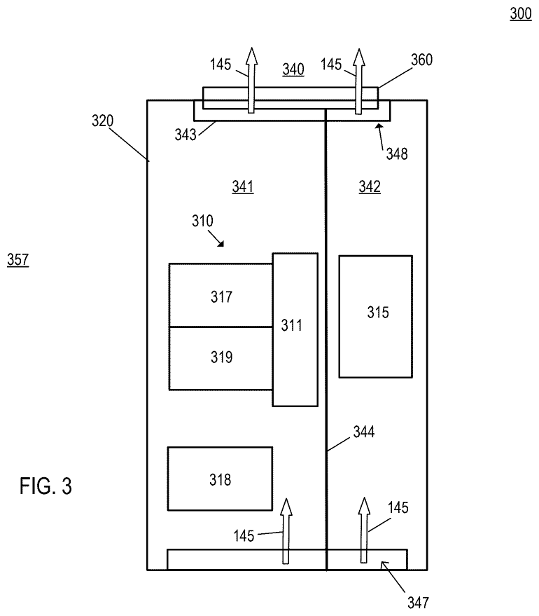

FIG. 3 is a side view of another example of a drive system 300. The drive system 300 includes a power converter 310 and a thermal management system 340. The thermal management system 340 promotes efficient flow of the thermal management fluid 145 through the drive system 300 to thereby cool the drive system 300 and/or maintain the components of the drive system 300 at a safe operating temperature.

The power converter 310 includes a rectifier system 317, an inverter system 319, an energy storage apparatus 318, and a heatsink 311. The heatsink 311 may be thermally coupled to any of the rectifier system 317, the inverter system 319, and the energy storage apparatus 318. In the example of FIG. 3, the heatsink 311 is thermally coupled to the rectifier system 317 and the inverter system 319. The energy storage apparatus 318 is any component or network of components that can store electrical energy. For example, the energy storage apparatus 318 may include a high-density film capacitor. The power converter 310 also includes a filter system 315 electrically connected to the rectifier system 317 and the energy storage apparatus 318. The filter system 315 may be direct current (DC) choke 315 that includes one or more inductors.

In operational use, the power converter 310 provides a time-varying or AC drive signal to a load (not shown). The drive system 300 may be used in a commercial, industrial, municipal, or industrial setting. For example, the drive system 300 may be used to drive a load that is part of a heating, ventilation, and air conditioning/refrigeration (HVAC/R) system; a water treatment facility; a fossil fuel extraction or refining process; a material-handling process; a conveying process; or a power plant, just to name a few.

The power converter 310 and DC choke 315 are mounted to a support 320. Similar to the support 120 of FIG. 1, the support 320 is any structure capable of supporting the power converter 310, DC choke 315, and other components of the drive system 300. For example, the support 320 may be an enclosure, a rack, or a frame. The support 320 is made of a durable and rugged material. Examples of materials that may be used for the support 320 include, without limitation, stainless steel, galvanized steel, or a rugged polymer. The support 320 includes two distinct fluid pathways 341 and 342, which are separated from each other by a wall 344. The support 320 also includes an inlet region 347 and an outlet region 348. The inlet region 347 and the outlet region 348 are in fluid communication with an exterior region 357.

The pathways 341 and 342 are open spaces through which the thermal management fluid 145 can flow. The heatsink 311 is in the fluid pathway 341. Some or all of the rectifier system 317, the inverter system 319, and the energy storage apparatus 318 also may be in the fluid pathway 341. The filter system 315 is in the fluid pathway 342.

The thermal management system 340 includes a fluid handling assembly 343 that is fluidly coupled to the outlet region 348. The fluid handling assembly 343 includes an active fluid driving element 360. The active fluid driving element 360 is any element capable of drawing the thermal management fluid 145 through the inlet region 347 into the fluid pathways 341 and 342, and expelling the thermal management fluid 145 from the support 320 through the outlet region 348. The active fluid driving element 360 may be, for example, a fan, a blower, a pump, or a combination of such elements.

As discussed above, the filter system 315 is in the fluid pathway 342, and the heatsink 311 is in the fluid pathway 341. When the thermal management fluid 145 flows in the fluid pathway 341, the thermal management fluid 145 transports heat away from the heatsink 311 and any portion of the rectifier system 317, the inverter system 319, and the energy storage apparatus 318 that is in thermal contact with the fluid pathway 341. Separately, the thermal management fluid 145 flows in the fluid pathway 342 and carries heat away from the filter system 315.

Thus, the filter system 315 is cooled separately from the heatsink 311, and the thermal management fluid 145 that flows by and/or through the heatsink 311 has not already absorbed heat from the filter system 315. The configuration of the support 320 and the inclusion of the distinct fluid pathways 341 and 342 promotes effective thermal management of the heatsink 311 and the filter system 315.

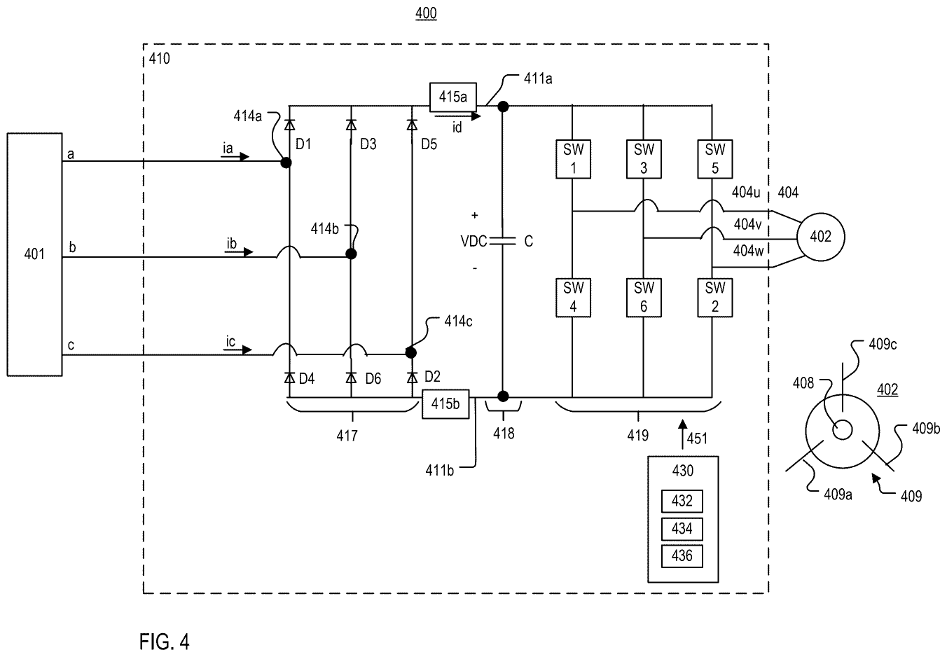

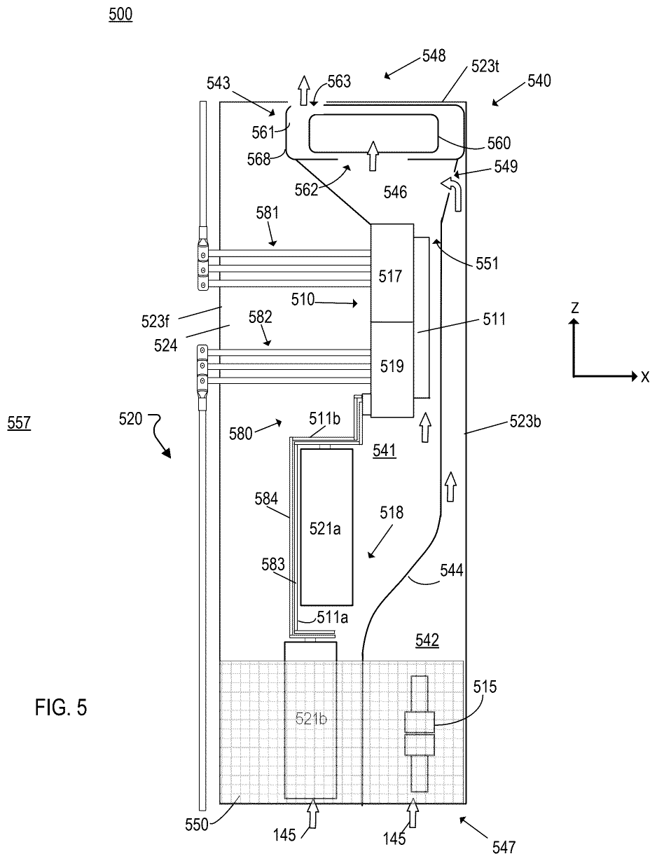

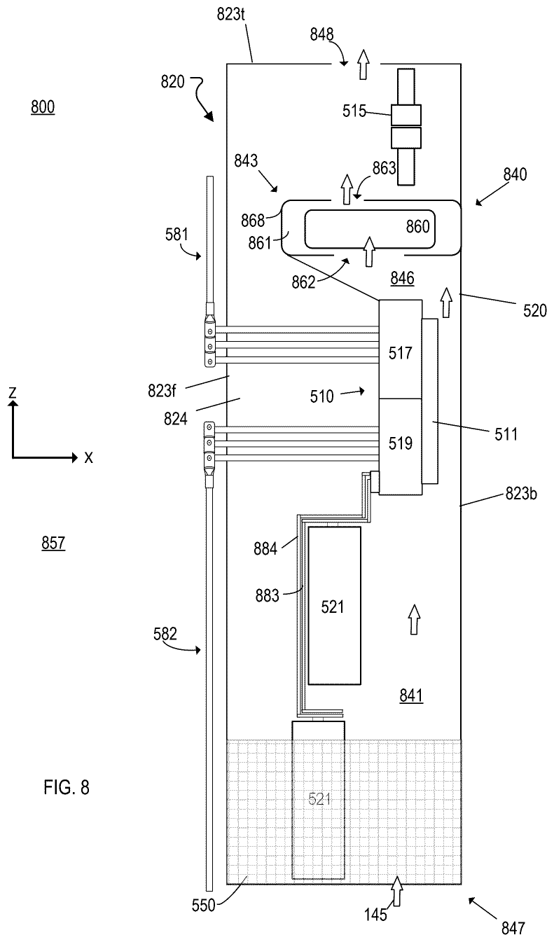

FIG. 4 is a schematic of an example of a drive system 400 that includes a power converter 410. The power converter 410 is an example of a power converter that may be used with a thermal management system such as the thermal management system 140, 240, 340, 540 (FIG. 5), or 840 (FIG. 8). The power converter 410 that includes a filter system 415, a rectifier 417, a DC link 418, and an inverter 419. In the example of FIG. 4, the filter system 415 is a DC choke 415. The inverter 419 provides a three-phase voltage 404 to a load 402. A control system 430 generates a switching command 451 that causes the controllable switches SW1 to SW6 to switch ON and OFF in a particular pattern to generate an inverter output voltage 404. The control system 430 may use a pulse width modulation (PWM) technique to generate the switching command 451.

In the example of FIG. 4, the load 402 is a three-phase motor 402, such as, for example, an induction motor or a permanent magnet synchronous machine. The motor 402 includes a stator 409, which is spatially fixed, and a rotor 408, which rotates relative to the stator 409 when the voltage 404 is applied. The stator 409 includes one electrical winding per phase: 409a, 409b, and 409c. Loads other than a motor may be used in the drive system 400.

An electrical power distribution network 401 distributes AC electrical power that has a fundamental frequency of, for example, 50 or 60 Hertz (Hz). The distribution network 401 may have an operating voltage of up to 690V. In some implementations, the distribution network 401 has an operating voltage greater than 690V. The distribution network 401 may include, for example, one or more transmission lines, distribution lines, electrical cables, and/or any other mechanism for transmitting electricity. The distribution network 401 includes three phases, which are referred to as a, b, and c.

The rectifier 417 is a three-phase six-pulse bridge that includes six electronic switches. In the example of FIG. 4, the six electronic switches are diodes D1, D2, D3, D4, D5, and D6 (referred to as diodes D1 to D6). Each diode D1 to D6 includes a cathode and an anode and is associated with a forward bias voltage. Each diode D1 to D6 allows current to flow in the forward direction (from the anode to the cathode) when voltage of the anode is greater than the voltage of the cathode by at least the bias voltage. When the voltage difference between the anode and the cathode is less than the forward bias voltage, the diode does not conduct current in the forward direction.

The power converter 410 includes input nodes 414a, 414b, 414c, each of which is electrically coupled to a respective one of the three phases a, b, c of the distribution network 401. The input node 414a is electrically connected to the anode of the diode D1 and the cathode of the diode D4. The input node 414b is electrically connected to the anode of the diode D3 and the cathode of the diode D6. The input node 414c is electrically connected to the anode of the diode D5 and the cathode of the diode D2. The diodes D1 to D6 rectify the input currents ia, ib, ic into a DC current id.

The diodes D1 to D6 are also electrically connected to the DC link 418. The cathode of each diode D1, D3, D5 is electrically connected to a positive DC bus 411a that is electrically connected to the DC link 418, and the anode of each diode D4, D4, D6 is electrically connected to a negative DC bus 411b that is electrically connected to the DC link 418. The DC link 418 includes a capacitor network C. The capacitor network C includes one or more capacitors that store electrical energy when the rectified current id flows from the rectifier 417 and discharge the stored electrical energy when the rectified current id does not flow from the rectifier 417. The capacitor network C may include one or more high-density film capacitors.

The DC choke 415 includes an inductor 415a in the positive DC bus 411a between the rectifier 417 and the DC link 418, and an inductor 415b in the negative DC bus 411b between the rectifier 417 and the DC link 418. The inductors 415a, 415b may be in any configuration. For example, the inductors 415a, 415b may be separate inductors. In some implementations, the inductors 415a, 415b may be integrated on a common magnetic core.

The inverter 419 includes a network of electronic switches SW1, SW2, SW3, SW4, SW5, and SW6 (referred to as switches SW1 to SW6) that are switched in accordance to the switching command 451 to generate the output voltage 404. Each of the switches SW1 to SW6 may be, for example, a power transistor.

The control system 430 generates the switching command 451, which controls the switching pattern of the switches SW1 to SW6 to generate the voltage 404 with particular characteristics (for example, amplitude, frequency, and/or phase). The control system 430 includes an electronic processing module 432, an electronic storage 434, and an input/output (I/O) interface 436. The electronic processing module 432 includes one or more electronic processors. The electronic processors of the module 432 may be any type of electronic processor and may or may not include a general-purpose central processing unit (CPU), a graphics processing unit (GPU), a microcontroller, a field-programmable gate array (FPGA), Complex Programmable Logic Device (CPLD), and/or an application-specific integrated circuit (ASIC).

The electronic storage 434 may be any type of electronic memory that is capable of storing data and instructions in the form of computer programs or software, and the electronic storage 434 may include volatile and/or non-volatile components. The electronic storage 434 and the processing module 432 are coupled such that the processing module 432 is able to access or read data from and write data to the electronic storage 434. The electronic storage 434 stores instructions that, when executed, cause the electronic processing module 432 to analyze data and/or retrieve information. The electronic storage 434 also may store information about the system 400. For example, the electronic storage 434 may store information about the motor 402 or the inverter 419. Additionally, the electronic storage 434 may store executable instructions that implement a PWM technique for generating the switching command 451.

The I/O interface 436 may be any interface that allows a human operator and/or an autonomous process to interact with the control system 430. The I/O interface 436 may include, for example, a display (such as a liquid crystal display (LCD)), a keyboard, audio input and/or output (such as speakers and/or a microphone), visual output (such as lights, light emitting diodes (LED)) that are in addition to or instead of the display, serial or parallel port, a Universal Serial Bus (USB) connection, and/or any type of network interface, such as, for example, Ethernet. The I/O interface 436 also may allow communication without physical contact through, for example, an IEEE 802.11, Bluetooth, or a near-field communication (NFC) connection. The control system 430 may be, for example, operated, configured, modified, or updated through the I/O interface 436.

The I/O interface 436 also may allow the control system 430 to communicate with components in the system 400 and with systems external to and remote from the system 400. For example, the I/O interface 436 may control a switch or a switching network (not shown) or a breaker within the system 400 that allows the power converter 410 to be disconnected from the distribution network 401. In another example, the I/O interface 436 may include a communications interface that allows communication between the control system 430 and a remote station (not shown), or between the control system 430 and a separate monitoring apparatus. The remote station or the monitoring apparatus may be any type of station through which an operator is able to communicate with the control system 430 without making physical contact with the control system 430. For example, the remote station may be a computer-based work station, a smart phone, tablet, or a laptop computer that connects to the control system 430 via a services protocol, or a remote control that connects to the control system 430 via a radio-frequency signal.

Other implementations are possible. For example, the rectifier 417 is shown as a diode-bridge front end based configuration. However, the rectifier 417 may have another configuration. For example, the rectifier 417 may be a hybrid diode-thyristor rectifier, a motor drive, or an active front end that includes six transistors or other controllable switches instead of the diodes D1 to D6.

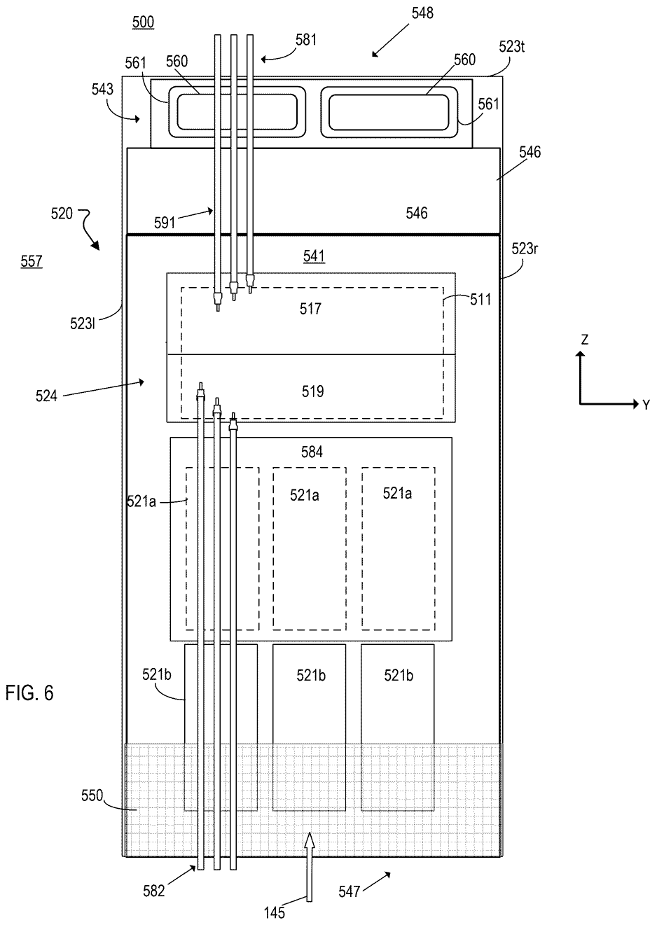

FIG. 5 is a side interior view of a three-phase drive system 500 that includes a thermal management system 540. FIG. 6 is a front interior view of the drive system 500. In FIG. 6, hidden elements are shown with a dashed line style. The thermal management system 540 provides efficient flow of the thermal management fluid 145 through the drive system 500 to thereby cool the drive system 500 and/or maintain the components of the drive system 500 at a safe operating temperature.

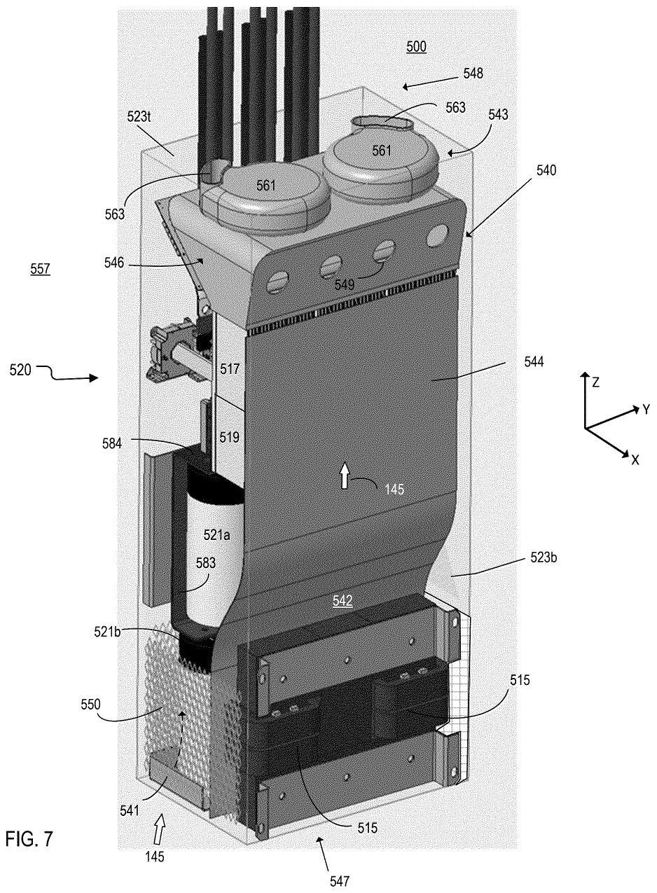

The drive system 500 includes an enclosure 520 and a power converter 510 in an interior 524 of the enclosure. Referring also to FIG. 7, which is a perspective rear view of the drive system 500 with the enclosure 520 shown as transparent to reveal the interior 524, the enclosure 520 is a six-sided parallelepiped. The enclosure 520 includes a top 523t, a right side 523r (FIG. 6), and a back side 523b. The enclosure 520 also includes a left side 523l (FIG. 6) opposite the right side 523r, and a front side 523f (FIG. 5) opposite the back side 523r. Other shapes and/or forms may be used for the enclosure 520.

The enclosure 520 is made of a durable and rugged material. Examples of materials that may be used for the enclosure 520 include, without limitation, stainless steel, galvanized steel, or a rugged polymer. The sides 523t, 523r, 523b, 523l, 523f may include openings such as vents, holes, or other features to allow for air flow and/or access to the interior 524. The enclosure 520 may include mounting elements, such as shelves, brackets, connections points, racks, and frames, in the interior 524. The power converter 510 is mounted to and/or supported by the mounting elements such that the components of the power converter 510 remain spatially fixed in the interior 524.

The power converter 510 includes a DC choke 515, a rectifier 517, an energy storage system 518, an inverter 519, and a heatsink 511. Referring also to FIG. 7, the DC choke 515 includes two inductors. The heatsink 511 is thermally coupled to the rectifier 517 and the inverter 519. At least some of the heat emitted by the rectifier 517 and the inverter 519 during use (for example, heat generated by transistors, capacitors, resistors, and/or electrical connections) is dissipated by the heatsink 511. The energy storage system 518 includes a bank of high-density film capacitors arranged as an upper row of high-density film capacitors 521a and a lower row of high-density film capacitors 521b. In the example shown in FIGS. 5-7, each row 521a, 521b includes three high-density film capacitors. More or fewer high-density film capacitors may be used.

The enclosure 520 includes distinct first and second fluid pathways 541 and 542 that are separated by a wall 544. As shown in FIG. 7, the wall 544 extends for the entire width (generally in the Y direction) of the enclosure 520. Each fluid pathway 541 and 542 is an open space that is fluidly coupled to an exterior region 557 around the enclosure 520 via an inlet region 547 and an outlet region 548. The wall 544 is a generally solid object that fluidly separates the pathway 541 from the pathway 542. For example, the wall 544 may be a piece of sheet metal or stainless steel. Each of the inlet region 547 and the outlet region 548 is an opening, for example, an open slot or a plurality of holes, that allow fluid exchange between the pathways 541 and 542 and the exterior region 557. In the drive system 500, the inlet region 547 is at the bottom of the enclosure 520 and the outlet region 548 is at the top side 523t of the enclosure 520.

Other implementations of the enclosure 520 are possible. For example, the inlet region 547 and/or the outlet region 548 may be on a side of the enclosure 520. Moreover, in the example shown in FIGS. 5-7, a mesh cover 550 is placed over the inlet region 547. The mesh cover 550 allows fluid to flow into the pathways 541 and 542 through the inlet region 547 but blocks at least some debris and objects from entering the pathways 541 and 542. The drive system 500 may be implemented without the mesh cover 550. In implementations that lack the mesh cover 550, the inlet region 547 may be formed of a collection of small openings that pass through a lower region of one or more of the sides 523b, 523r, 523l, 523f and/or the bottom of the enclosure 520 and are fluidly coupled to the pathways 541 and 542. Such openings allow fluid to flow into the pathways 541 and 542 while also preventing some or all debris and objects from entering the pathways 541 and 542. Moreover, the mesh cover 550 may be used in an implementation that uses a collection of small openings for the inlet region 547 to further promote debris removal. In the example of FIG. 5, the rectifier 517, the inverter 519, the energy storage apparatus 518, and the heatsink 511 are in thermal contact with the first fluid pathway 541 and/or are placed directly in the first fluid pathway 541. The DC choke 515 is in the second fluid pathway 542. The DC choke 515 is a relatively heavy object. Placing the DC choke 515 near the bottom of the enclosure 520 improves the stability of the enclosure 520 when the enclosure 520 is installed upright.

The thermal management system 540 includes a chamber 546 fluidly coupled to a fluid handling assembly 543 and the fluid pathways 541 and 542. The fluid handling assembly 543 includes one or more fluid movers 568, each of which includes an active element 560, a housing 561 having an inlet 562 fluidly coupled to the chamber 546, and an outlet 563 open to the exterior region 557.

The drive system 500 further includes a busbar assembly 580. The busbar assembly 580 includes a plurality of busbars that are, for example, electrically conductive bars, rods, or strips. The busbars of the busbar assembly 580 are made of any electrically conductive material, such as, for example, copper, gold, aluminum, brass, or a metal alloy. The busbar assembly 580 includes input busbars 581 that are each electrically connected to a respective phase of the rectifier 517 of the power converter 510 and output busbars 582 that are each electrically connected to a respective phase of the output of the inverter 519 of the power converter 510.

The busbar assembly 580 also includes a positive DC bus 511a and a negative DC bus 511b, each of which is electrically connected to the energy storage system 518, the inverter 519, and to one of the inductors of the DC choke 515. Each DC bus 511a, 511b includes a respective plate bar 583, 584. The plate bars 583, 584 are electrically conductive plate structures that are electrically connected to a positive terminal of the high-density film capacitors 521. An insulative material (not show) is between the plate bars 583, 584 to maintain electrical isolation between the plate bars 583, 584. The plate bars 583, 584 extend outward over the terminals of the high-density film capacitors 521a, over a front side of the high-density film capacitors 521a, and extend inward over the terminals of the high-density film capacitors 521a. The plate bars 583, 584 create a partial physical barrier on one side of the pathway 541 but the high-density film capacitors 521a and 521b do not block or substantially restrict the flow of the thermal management fluid 145 to the heatsink 511.

During operation of the drive system 500, the one or more active elements 560 draw the thermal management fluid 145 into the first and second fluid pathways 541, 542 through the inlet region 547. The thermal management fluid 145 that flows in the first pathway 541 comes into thermal contact with all or part of the energy storage apparatus 518, the inverter 519, the rectifier 517, and the heatsink 511. The thermal management fluid 145 absorbs heat from one or more of these elements and continues to flow through the pathway 541, and then flows into the chamber 546 through an open region 551. The thermal management fluid 145 that flows in the second fluid pathway 542 flows past and/or through the DC choke 515, absorbing heat from the DC choke 515, and then flowing into the chamber 546 through an open region 549. As shown in FIG. 7, the open region 549 includes a plurality of openings that pass through a sidewall of the chamber 546.

The thermal management fluid 145 in the chamber 546 enters the housing 561 of the fluid movers 568 through the inlet 562 and is expelled through the outlet 563, which is fluidly coupled to the exterior region 557. The outlet 563 of the housing 561 is in the interior 524 of the enclosure 520 near the top side 523t.

During operation of the power converter 510, the DC choke 515 generates a significant amount of heat. The wall 544 separating the first fluid pathway 541 from the second fluid pathway 542 substantially prevents direct fluid exchange between the pathways 541 and 542. Thus, the thermal management fluid 145 heated by the DC choke 515 flows into the chamber 546 and is prevented from interacting with and heating the other components of the power converter 510 (for example, the heatsink 511, the rectifier 517, inverter 519, and/or the energy storage apparatus 518). The distinct fluid pathways 541 and 542 allow the DC choke 515 and the heatsink 511 to be cooled separately.

Moreover, the DC choke 515 may have a relatively high weight. Placing the DC choke 515 near the bottom of the enclosure 520 brings the center of mass of the drive system 500 closer to the floor or other object upon which the enclosure 520 rests. This reduces the chances of the drive system tipping over after being installed upright. Additionally, placement of the DC choke 515 near the bottom of the fluid pathway 542 provides additional space for thermal management fluid 145 heated by the DC choke 515 to cool prior to reaching the chamber 546.

FIG. 8 is a side view of another three-phase drive system 800. The drive system 800 includes the power converter 510 and a thermal management system 840 in an interior 824 of an enclosure 820. The enclosure 820 may be, for example, a six-sided housing. In the example of FIG. 8, a front side 823f, a top side 823t, and a back side 823b are labeled. In the drive system 800, the power converter 510 is arranged with the DC choke 515 near the top side 523t of the enclosure 820 instead of near the bottom of the enclosure 820. The enclosure 820 includes a single fluid pathway 841 that is fluidly coupled to an exterior region 857 via an inlet region 847 and an outlet region 848. The rectifier 517, the inverter 519, the energy storage apparatus 518, and the heatsink 511 are in thermal contact with the fluid pathway 841.

The thermal management system 840 includes a fluid handling assembly 843. The fluid handling assembly 843 includes a chamber 846 and one or more fluid movers 868, each including an active element 860. The fluid mover 868 includes a housing 861 with an inlet 862 and an outlet 863. The active element 860 is in the housing 861. The chamber 846 is fluidly coupled to the fluid pathway 841 and to the inlet 862.

The fluid handling assembly 843 draws the thermal management fluid 145 through the inlet region 847 and through the fluid pathway 841. As the thermal management fluid 145 flows through the fluid pathway 841, the thermal management fluid 145 carries heat away from the heatsink 511 (and also may transport heat away from the rectifier 517, the inverter 519, and/or the energy storage apparatus 518). The heated thermal management fluid 145 flows into the chamber 846. The heated thermal management fluid 145 cools as it expands in the chamber 846. The fluid handling assembly 843 continues to cause the thermal management fluid 145 to flow, drawing the thermal management fluid 145 from the chamber 846 into the housing 861 and expelling it out of the outlet 863. The outlet 863 is oriented such that the expelled thermal management fluid 145 flows toward and past the DC choke 515. As the thermal management fluid 145 flows by the DC choke 515, the fluid 145 carries heat away from the DC choke 515 and then exits the enclosure 820 through the outlet region 848.

In the configuration shown in FIG. 8, the heatsink 511 is cooled before the DC choke 515. The inverter 519 and the rectifier 517 tend to generate less heat than the DC choke 515 during operation of the power converter 510. The configuration shown in FIG. 8 ensures that the heatsink 511 is cooled before the thermal management fluid 145 is heated by the DC choke 515 even though the enclosure 820 includes just the one fluid pathway 841.

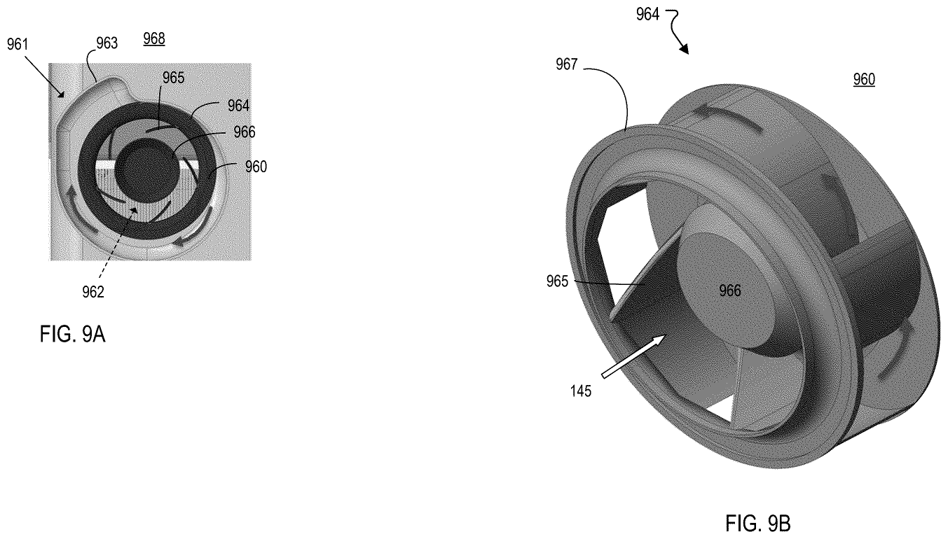

FIG. 9A is a cross-sectional view of an example a fluid mover 968 that includes an active element 960 in a housing 961. FIG. 9B is a perspective view of the active element 960. The fluid mover 968 may be used as the fluid mover 568 or the fluid mover 868. The active element 960 is a centrifugal-type blower that includes an impeller 964 with curved blades 965 mounted on a central hub 966. The curved blades 965 extend from the central hub 966 to a rim 967.

The housing 961 of the centrifugal-type blower 960 is a volute-type housing with an inlet 962 and an outlet 963. The blower 960 is configured to move the thermal management fluid 145 from an inlet 962 of a housing 961 to an outlet 963 of the housing 961 through the use of centrifugal force generated by the rotating impeller 964. In operation, the rotating impeller 964 of the centrifugal-type blower 960 generates rotational flows roughly perpendicular to the axis of rotation. The interior of the housing 961 (FIG. 9A) has an expanding spiral shape that increases in volume toward the outlet 963. As the impeller 964 rotates and creates centrifugal force, the thermal management fluid 145 is drawn into the housing 961 toward a central area of the impeller 964. The impeller 964 then propels the thermal management fluid 145 in an outward direction inside the housing 961 due to the centrifugal force acting upon it. The expanding spiral shaped housing 961 transforms the high-velocity, low-pressure flow of thermal management fluid 145 generated by the impeller 964 into a higher-pressure, lower-velocity flow that is forced out of the housing 961 through the outlet 963.

The low profile of the housing 961 of the centrifugal-type blower 960 allows the extent of the enclosure 520, 820 in the Z direction to be smaller than it would be using a blower with a larger housing. Moreover, the housing 961 can be rotated in the X-Y plane to change the position of the outlet 963 (and thus the direction in which the heated fluid is expelled) without changing the design of the enclosure 520, 820.

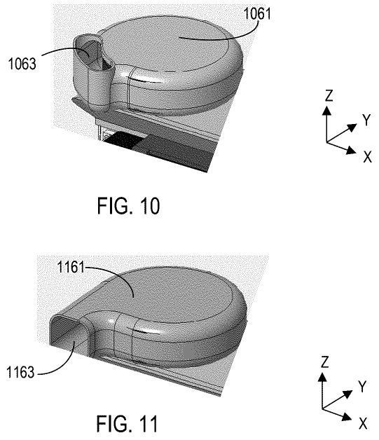

FIG. 10 is a perspective exterior view of an example of a housing 1061 that may be used as the housing 961. In the housing 1061, an outlet 1063 is located at the top of the housing 1061 to direct expelled air generally in the Z direction. FIG. 11 shows another example of a housing 1161 that may be used as the housing 1061. The housing 1161 includes an outlet 1163 located at the side of the housing 1161. The outlet 1163 directs expelled air generally in the X-Y plane. Either of the housings 1061 and 1161 may be used with the blower 960.

These and other implementations are within the scope of the claims.

What is claimed is:

1. A drive system comprising:
a power converter comprising:
a rectifier;
an inverter;
a heatsink thermally coupled to one or more of the rectifier and the inverter;
an energy storage apparatus electrically connected to the rectifier and the inverter; and
a direct current (DC) choke electrically connected to the rectifier and the energy storage apparatus; and
a thermal management system configured to flow a thermal management fluid to transport heat away from the DC choke and to separately transport heat away from the heatsink.

2. The drive system of claim 1, wherein the thermal management system is configured to flow the thermal management fluid in a first fluid pathway and a second fluid pathway that is at least partially distinct from the first fluid pathway, wherein the heatsink is in the first fluid pathway, and the DC choke is in the second fluid pathway.

3. The drive system of claim 1, wherein the energy storage apparatus includes one or more power film capacitors.

4. The drive system of claim 1, wherein the thermal management system comprises a fluid handling assembly configured to intake a thermal management fluid at an inlet region and to expel the thermal management fluid through an outlet region.

5. The drive system of claim 4, wherein the fluid handling assembly comprises a blower.

6. The drive system of claim 4, wherein the inlet region is configured to intake the thermal management fluid from the heatsink and the outlet region is configured to expel the thermal management fluid through the outlet region and toward the DC choke.

7. The drive system of claim 6, wherein, in operational use, the DC choke is above the fluid handling assembly.

8. The drive system of claim 4, wherein the fluid handling assembly is configured to: flow the thermal management fluid in a first fluid pathway past the heatsink and through the inlet region, flow the thermal management fluid in a second fluid pathway past the DC choke and through the inlet region, and expel the thermal management fluid from the first fluid pathway and the second fluid pathway through the outlet region.

9. The drive system of claim 4, wherein the outlet region of the fluid handling assembly is adjustable such that a direction fluid is expelled through the outlet region is adjustable.

10. The drive system of claim 4, wherein the fluid handling assembly comprises one or more blowers, and the thermal management fluid comprises air.

11. The drive system of claim 2, further including a wall separating the first fluid pathway and the second fluid pathway.

12. The drive system of claim 1, further comprising:
an enclosure, wherein the rectifier, the inverter, the heatsink, the energy storage apparatus, and the DC choke are inside the enclosure; and, in operational use, the DC choke is in a bottom portion of the enclosure.

13. The drive system of claim 1, further comprising:
an enclosure, wherein the rectifier, the inverter, the heatsink, the energy storage apparatus, and the DC choke are inside the enclosure; and, in operational use, the DC choke is in a top portion of the enclosure.

14. The drive system of claim 1, further comprising an enclosure, and wherein the enclosure is configured for placement in a first type of mounting arrangement in a first position, and the enclosure is configured for placement in a second type of mounting arrangement in a second position.

15. The drive system of claim 14, wherein the first type of mounting arrangement comprises a wall mount arrangement, and the second type of mounting arrangement comprises a floor mount arrangement.

16. An enclosure for a drive system, the enclosure comprising:
a region configured to receive an energy storage apparatus and an electronics module comprising a heat sink;
a first fluid pathway configured to transport a thermal management fluid to cool the heat sink;
a second fluid pathway configured to transport the thermal management fluid to cool a filter assembly, the filter assembly configured to be electrically connected to the electronics module and the energy storage apparatus; and
a fluid handling assembly configured to:
direct the thermal management fluid through the first fluid pathway and the second fluid pathway; and
to expel the thermal management fluid to a region outside of the enclosure.

17. The enclosure of claim 16, wherein the fluid handling assembly comprises one or more blowers, and the thermal management fluid comprises air.

18. A method comprising:
transporting heat away from a first portion of a power converter, the first portion of the power converter comprising a heatsink thermally coupled to one or more of an inverter, a rectifier, and an energy storage apparatus; and
separately transporting heat away from a second portion of the power converter, the second portion of the power converter comprising a filter assembly electrically connected to the rectifier and the energy storage apparatus.

19. The method of claim 18, wherein separately transporting heat away from the second portion of the power converter comprises transporting a thermal management fluid past the filter assembly after passing the thermal management fluid past the heat sink.

20. The method of claim 18, wherein separately transporting heat away from the second portion of the power converter comprises transporting a thermal management fluid in a first fluid pathway past the heat sink and in a second fluid pathway past the filter assembly.
